(19) United States
(12) Patent Application Publication
(10) Pub. No.: US 2007/0197001 A1
(43) Pub. Date: Aug. 23, 2007

(54) Method of manufacturing chip resistors

(75) Inventors: Shiow-Chang Luh, Fongshan City (TW); Chun-Hsiung Kuo, Kaohsiung (TW)

Correspondence Address: CHARLES E. BAXLEY, ESQ., 90 JOHN STREET, THIRD FLOOR, NEW YORK, NY, 10038, US

(73) Assignee: Walsin Technology Corp.

(21) Appl. No.: 11/643,338

(22) Filed: Dec. 21, 2006

(30) Foreign Application Priority Data
Feb. 22, 2006 (TW) 095105895

(51) Int. Cl. H01L 21/30; H01L 21/46

(52) U.S. Cl. 438/458

(57) ABSTRACT

A method of manufacturing chip resistors has steps of cutting grooves on a substrate, forming through holes, defining chip regions, forming main electrodes, forming resistor layers, forming primary protective layers, dividing the substrate into multiple strips, forming inner electrodes, cutting the strips into multiple chip resistor units and plating outer electrodes. The step of cutting grooves on a substrate includes forming multiple grooves parallel to each other on a substrate. The step of forming through holes includes forming multiple through holes between and across each two adjacent grooves on the substrate, and each through hole has smooth inner walls. The step of dividing the substrate into multiple strips includes cutting the substrate along and perpendicular to the through holes. The step of cutting the strips into multiple chip resistor units includes cutting the strips along the grooves into multiple chip resistor units.

### BACKGROUND OF THE INVENTION

1. Field of the Invention

The present invention relates to a method of manufacturing chip resistors, and more particularly to a method of manufacturing chip resistors that increases the production efficiency and yield.

2. Description of Related Art

Because electronic products are becoming smaller, individual active and passive electronic elements have to become smaller, too. For example, standard chip resistors may be 0.60 mm in length, 0.30 mm in width and 0.23 mm in depth or 0.40 mm in length, 0.20 mm in width and 0.23 mm in depth. Smaller elements have smaller tolerances for error.

With reference to FIG. 3, a conventional manufacturing method comprises steps of cutting grooves (31, 32) on a substrate (30), defining chip regions (33), forming main electrodes (34), forming resistor layers (35), forming inner protective layers (36), adjusting resistance, forming outer protective layers (37), dividing the substrate (30) into multiple strips (30′), forming inner electrodes (38), cutting the strips (30′) into multiple chip resistor units (40) and plating outer electrodes (39).

The step of cutting grooves (31, 32) on a substrate (30) comprises mechanically cutting multiple parallel grooves (31) and multiple perpendicular grooves (32) on a substrate (30) with a cutting blade.

The step of defining chip regions (33) comprises defining multiple chip regions (33) between adjacent parallel grooves (31) and perpendicular grooves (32).

The step of forming main electrodes (34) comprises printing and firing metal organic paste on the top and bottom surfaces of a substrate (30) to form a pair of main electrodes (34) in each chip region (33). For example, a chip resistor having size of 0.60 mm in length, 0.30 mm in width and 0.23 mm in depth requires each main electrode (34) to be at least 0.15 mm in length.

The step of forming resistor layers (35) comprises printing and firing resistor elements between the two main electrodes (34) in each chip region (33) to form multiple resistor layers (35).

The step of forming inner protective layers (36) comprises printing and firing protective glaze on the resistor layers (35) to form multiple inner protective layers (36).

The step of adjusting resistance comprises carving the inner protective layers (36) and resistor layers (35) with a laser beam to adjust resistance of the resistor layers (35).

The step of forming outer protective layers (37) comprises forming multiple outer protective layers (37) on the inner protective layers (36).

The step of dividing the substrate (30) into multiple strips (30′) comprises cutting the substrate (30) along the perpendicular grooves (32) with a laser beam or a rotating blade to divide the substrate (30) into multiple strips (30′). Each strip (30′) has two cut edges opposite to each other.

The step of forming inner electrodes (38) comprises sputtering inner electrodes (38) respectively on the cut edges of each strip (30′) by vacuum sputtering. The inner electrodes (38) connect the main electrodes (34) respectively on the top and bottom surfaces of the substrate (30).

The step of cutting the strips (30′) into multiple chip resistor units (40) comprises cutting the strips (30′) along the parallel grooves (31) into multiple chip resistor units (40).

The step of plating outer electrodes (39) comprises plating outer electrodes (39) on the inner electrodes (38) by barrel plating. Therefore, multiple chip resistors (R) are finished after plating outer electrodes (39) on the chip resistor units (40).

However, the conventional method has the following shortcomings.

1. The substrate (30) is easily broken during the printing and firing processes because the substrate (30) has multiple parallel grooves (31) and perpendicular grooves (32) cut into surfaces of the substrate (30).

2. With further reference to FIG. 4, the inner electrodes (38) may have different thicknesses because the cut edges of each strip (30′) are not smooth when the substrate (30) is divided into multiple strips (30′). Therefore, conductivity of the inner electrodes (38) will vary and adversely influence yield due to inconsistent thickness of the inner electrodes (38).

To overcome the shortcomings, the present invention provides a method of manufacturing chip resistors to mitigate or obviate the aforementioned problems.

### SUMMARY OF THE INVENTION

The main objective of the invention is to provide a method of manufacturing chip resistors that increases production efficiency and yield.

A method of manufacturing chip resistors in accordance with the present invention comprises steps of cutting grooves on a substrate, forming through holes, defining chip regions, forming main electrodes, forming resistor layers, forming primary protective layers, dividing the substrate into multiple strips, forming inner electrodes, cutting the strips into multiple chip resistor units and plating outer electrodes. The step of cutting grooves on a substrate comprises forming multiple grooves parallel to each other on a substrate. The step of forming through holes comprises forming multiple through holes between and across each two adjacent grooves on the substrate, and each through hole has smooth inner walls. The step of dividing the substrate into multiple strips comprises cutting the substrate along and perpendicular to the through holes. The step of cutting the strips into multiple chip resistor units comprises cutting the strips along the grooves into multiple chip resistor units.

Other objectives, advantages and novel features of the invention will become more apparent from the following detailed description when taken in conjunction with the accompanying drawings.

### BRIEF DESCRIPTION OF THE DRAWINGS

FIG. 1 is operational views of a method of manufacturing chip resistors in accordance with the present invention;

FIG. 2 is a cross sectional side view of a chip resistor manufactured by the method in FIG. 1;

FIG. 3 is operational views of a conventional method of manufacturing chip resistors; and

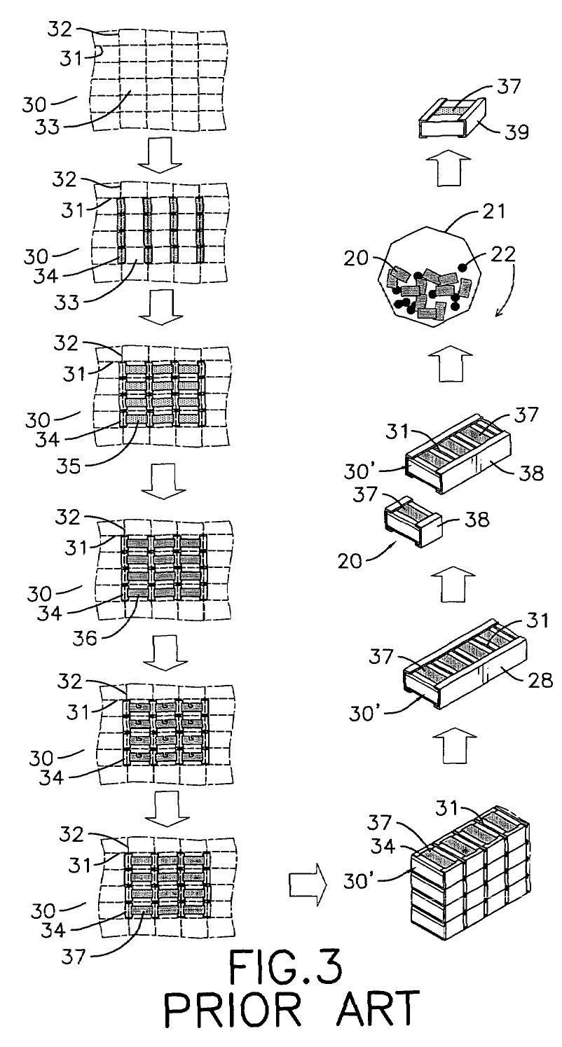

FIG. 4 is a cross sectional side view of a chip resistor manufactured by the conventional method in FIG. 3 without the inner and outer electrodes.

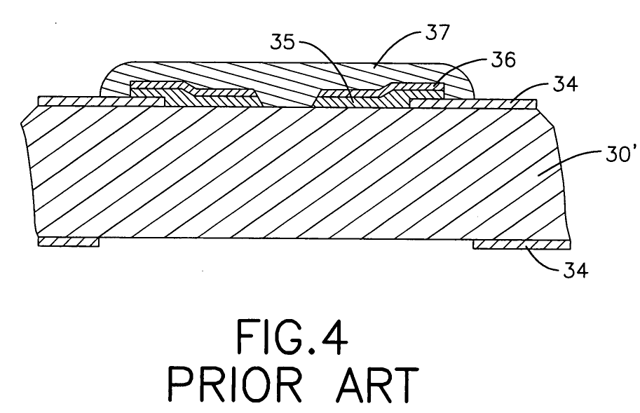

### DETAILED DESCRIPTION OF PREFERRED EMBODIMENT

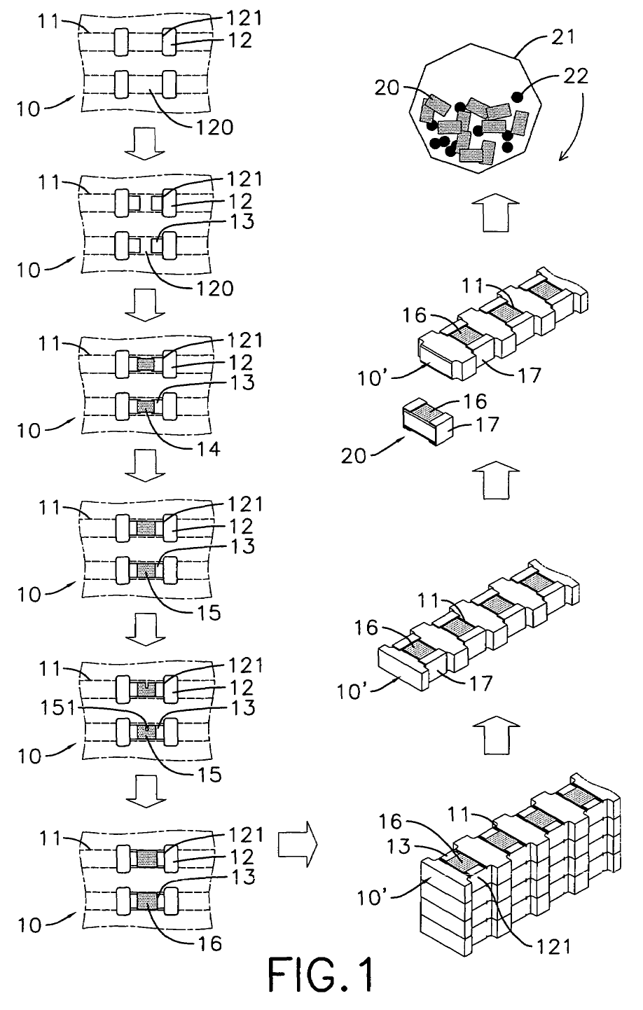

With reference to FIG. 1, a method of manufacturing chip resistors in accordance with the present invention comprises steps of cutting grooves (11) in a substrate (10), forming through holes (12), defining chip regions (120), forming main electrodes (13), forming resistor layers (14), forming primary protective layers (15), optionally adjusting resistance, optionally forming second protective layers (16), dividing the substrate (10) into multiple strips (10′), forming inner electrodes (17), cutting the strips (10′) into multiple chip resistor units (20) and plating outer electrodes (18).

The step of cutting grooves (11) on a substrate (10) may be performed with a blade and comprises cutting multiple grooves (11) parallel to each other on a substrate (10). The substrate (10) has a thickness, a top surface and a bottom surface. Each groove (11) has a depth, and the depth of each groove (11) may not be deeper than half the thickness of the substrate (10).

The step of forming through holes (12) comprises forming multiple through holes (12) through the substrate (10). The through holes (12) are formed between and across two adjacent grooves (11), and each through hole (12) is separated from other through holes (12) and has smooth inner walls (121).

The step of defining chip regions (120) comprises defining multiple chip regions (120), and each chip region (120) is between adjacent through holes (12) and is arranged in a matrix.

The step of forming main electrodes (13) may be performed by printing and firing processes and comprises forming main electrodes (13) respectively on the chip regions (120) in pairs on the top and bottom surfaces of the substrate (10) and respectively on the edges of the through holes (12).

The step of forming resistor layers (14) may be performed by printing and firing processes and comprises forming resistor layers (14) on each chip region (120). The resistor layers (14) are electronically connected to the main electrodes (13) and entirely cover the exposed part of the chip region (120), and each resistor layer (14) has a resistance and is electronically connected to the main electrodes (13) in the corresponding chip region (120).

The step of forming primary protective layers (15) may be performed by printing and firing processes and comprises forming multiple primary protective layers (15) respectively on the chip regions (120) to entirely cover the resistor layers (14).

The step of adjusting resistance comprises carving the primary protective layers (15) and resistor layers (14) with a laser beam to adjust resistance of the resistor layers (14).

The step of forming second protective layers (16) may be performed by printing and firing processes and comprises forming multiple second protective layers (16) respectively on and entirely covering the primary protective layers (15) to protect the resistor layers (14).

The step of dividing the substrate (10) into multiple strips (10′) comprises cutting the substrate (10) along and perpendicular to the through holes (12) with a laser beam, a rotating blade or a mechanical cutter to divide the substrate (10′). Each strip (10′) has two cut edges opposite to each other.

The step of forming inner electrodes (17) may be performed by vacuum sputtering or vapor deposition and comprises plating inner electrodes (17) respectively on the cut edges of each strip (10′). The inner electrodes (17) connect the main electrodes (14) respectively on the top and bottom surfaces of the substrate (10).

The step of cutting the strips (10′) into multiple chip resistor units (20) comprises cutting the strips (10′) along the grooves (11) into multiple chip resistor units (20) with a laser beam, a rotating blade or a mechanical cutter.

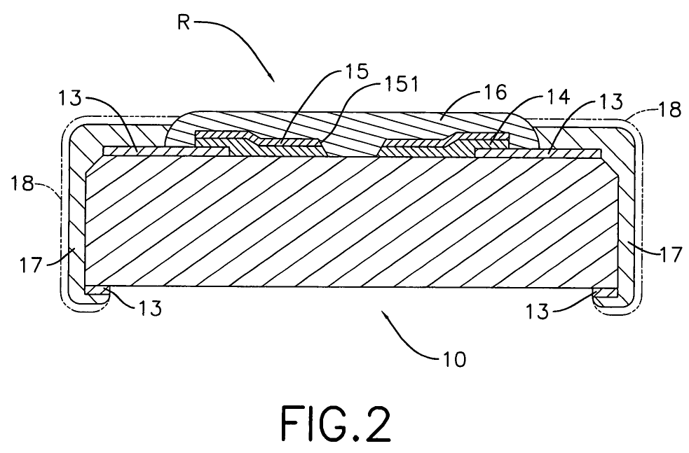

With further reference to FIG. 2, the step of plating outer electrodes (18) may be performed by barrel plating and comprises plating outer electrodes (18) on the inner electrodes (17). Therefore, multiple chip resistors (R) are finished after plating outer electrodes (18) on the chip resistor units (20).

Such a method has the following advantages.

1. The substrate (10) is less likely to be broken during printing and firing processes because the method forms fewer grooves (11) does on the substrate (10) than the conventional method and the grooves (11) do not intersect.

2. The inner electrodes (17) are plated on the inner walls (121) of the through holes (12) and are flat because the inner walls (121) are smooth. Therefore, the outer electrodes (18) plated on the inner electrodes (17) are also smooth and flat.

3. All chip regions (120) have the same size because each chip region (120) is defined between two through holes (12). Therefore, all chip resistors (R) are the same size in length.

Even though numerous characteristics and advantages of the present invention have been set forth in the foregoing description, together with details of the structure and function of the invention, the disclosure is illustrative only. Changes may be made in detail, especially in matters of arrangement of parts within the principles of the invention to the full extent indicated by the broad general meaning of the terms in which the appended claims are expressed.

What is claimed is:

1. A method of manufacturing chip resistors comprising steps of:
cutting grooves on a substrate comprising forming multiple grooves parallel to each other on a substrate having a top surface and a bottom surface;
forming through holes comprising forming multiple through holes through the substrate between and across each two adjacent grooves on the substrate, and each through hole being separated from other through holes and having smooth inner walls;
defining chip regions comprising defining multiple chip regions, and each chip region being between adjacent through holes and being arranged in a matrix;
forming main electrodes comprising forming multiple main electrodes respectively on the top and bottom surfaces of the substrate on the chip regions in pairs and respectively on the edges of the through holes;
forming resistor layers comprising forming resistor layers on each chip region electronically connected to the main electrodes and entirely covering the exposed part of the chip region, and each resistor layer has a resistance;
forming primary protective layers comprising forming multiple primary protective layers respectively on the chip regions to entirely cover the resistor layers;
dividing the substrate into multiple strips comprising cutting the substrate along and, perpendicular to the through holes to divide the substrate into multiple strips, and each strip having two cut edges opposite to each other;
forming inner electrodes comprising plating multiple inner electrodes respectively on the cut edges of each strip electronically connected to the main electrodes on the top and bottom surfaces of the substrate;
cutting the strips into multiple chip resistor units comprising cutting the strips along the grooves into multiple chip resistor units; and
plating outer electrodes comprising plating outer electrodes respectively on the inner electrodes.

2. The method as claimed in claim 1, wherein after the step of forming primary protective layers the method further comprises steps of
adjusting resistance comprising carving the primary protective layers and resistor layers with a laser beam to adjust resistance of the resistor layers; and
forming second protective layers comprising forming multiple second protective layers respectively on and entirely covering the primary protective layers to protect the resistor layers.

3. The method as claimed in claim 1, wherein
each substrate has a thickness; and
each groove has a depth being not deeper than half the thickness of the substrate.

4. The method as claimed in claim 1, wherein the steps of forming main electrodes, forming resistor layers and forming primary protective layers are performed by printing and firing processes.

5. The method as claimed in claim 1, wherein the step of forming inner electrodes is performed by vacuum sputtering.

6. The method as claimed in claim 1, wherein the step of forming inner electrodes is performed by vapor deposition.

7. The method as claimed in claim 1, wherein the steps of dividing the substrate into multiple strips and cutting the strips into multiple chip resistor units are performed by a laser beam.

8. The method as claimed in claim 1, wherein the steps of dividing the substrate into multiple strips and cutting the strips into multiple chip resistor units are performed by a mechanical cutter.

9. The method as claimed in claim 1, wherein the steps of dividing the substrate into multiple strips and cutting the strips into multiple chip resistor units are performed by a rotating blade.

10. The method as claimed in claim 1, wherein the step of plating outer electrodes is performed by barrel plating.

11. The method as claimed in claim 2, wherein
each substrate has a thickness; and
each groove has a depth being not deeper than half the thickness of the substrate.

12. The method as claimed in claim 2, wherein the steps of forming main electrodes, forming resistor layers, forming primary protective layers and forming second protective layers are performed by printing and firing processes.

13. The method as claimed in claim 2, wherein the step of forming inner electrodes is performed by vacuum sputtering.

14. The method as claimed in claim 2, wherein the step of f,ring inner electrodes is performed by vapor deposition.

15. The method as claimed in claim 2, wherein the steps of dividing the substrate into multiple strips and cutting the strips into multiple chip resistor units are performed by a laser beam.

16. The method as claimed in claim 2, wherein the steps of dividing the substrate into multiple strips and cutting the strips into multiple chip resistor units are performed by a mechanical cutter.

17. The method as claimed in claim 2, wherein the steps of dividing the substrate into multiple strips and cutting the strips into multiple chip resistor units are performed by a rotating blade.

18. The method as claimed in claim 2, wherein the step of plating outer electrodes is performed by barrel plating.
